(19) United States
(12) Patent Application Publication
(10) Pub. No.: US 2019/0077991 A1
(43) Pub. Date: Mar. 14, 2019

(54) POLISHING COMPOSITION AND POLISHING METHOD USING SAME, AND METHOD FOR PRODUCING POLISHING-COMPLETED OBJECT TO BE POLISHED USING SAME

(71) Applicant: FUJIMI INCORPORATED, Kiyosu-shi, Aichi (JP)

(72) Inventors: Toshio SHINODA, Kiyosu-shi, Aichi (JP); Takahiro UMEDA, Kiyosu-shi, Aichi (JP); Shota SUZUKI, Kiyosu-shi, Aichi (JP)

(73) Assignee: FUJIMI INCORPORATED, Kiyosu-shi, Aichi (JP)

(21) Appl. No.: 15/765,572

(22) PCT Filed: Sep. 8, 2016
(86) PCT No.: PCT/JP2016/076530

§ 371 Date: Apr. 3, 2018

(30) Foreign Application Priority Data
Oct. 9, 2015 (JP) 2015-201340

(51) Int. Cl. C09G 1/02; H01L 21/3105

(52) U.S. Cl. CPC C09G 1/02; H01L 21/31053

(57) ABSTRACT

The present invention provides a means for further improving a polishing speed in a polishing composition.

The polishing composition includes: an abrasive grain; hydrogen peroxide; and water, wherein the abrasive grain has an average secondary particle size of 20 nm or more to 150 nm or less, a molar concentration M (mmol/Kg) of the hydrogen peroxide and a total surface area of the abrasive grain satisfy a relationship of Formula 1 below and Formula 2 below, and a pH is 10 or more to 14 or less.

M<Log(S)×100−750 (Formula 1)

M>0 (Formula 2)
(wherein S represents a total surface area (m²) of abrasive grains present in 1 Kg of the polishing composition, and Log(S) represents a natural logarithm of S).

### TECHNICAL FIELD

The present invention relates to a polishing composition, a polishing method using the same, and a method for producing a polishing-completed object to be polished using the same.

### BACKGROUND ART

A semiconductor device represented by a silicon semiconductor has been miniaturized and highly-integrated in response to market demands such as high performance and miniaturization. Accordingly, a high planarization technique for producing a fine wiring pattern is essential, and thus a chemical mechanical polishing (CMP) process for polishing a wafer surface using a polishing slurry which is a polishing composition comprising alumina or silica fine grains (hereinafter, abbreviated as a CMP slurry) has been introduced in a process for producing a semiconductor.

In addition, in recent years, for example, as one of the high integration technologies, a technology for producing an electrode by forming a narrow via penetrating a semiconductor substrate such as silicon, and filling the via with a conductor such as copper or tungsten, (through-silicon via: TSV), is under development. When the electrode is produced, the CMP process is also used to perform thinning and planarization of the semiconductor substrate.

The polishing composition used for these usages has been reviewed in order to implement excellent polishing characteristics from various viewpoints such as improvement in a polishing speed, improvement in flatness of a polishing-completed object to be polished, prevention of clogging of the filter, improvement in lifetime of a polishing composition, or suppression of environmental load.

For example, Japanese Patent Laid-Open Publication No. H05-154760 discloses that a high polishing speed is capable of being implemented and a superior polished surface is capable of being obtained by a polishing composition for a silicon wafer comprising colloidal silica sol or silica gel, and a predetermined amount of piperazine.

In addition, for example, International Publication No. 2008/004320 (corresponding to U.S. Patent Application Publication No. 2009/311947) discloses that excellent smoothness is capable of being obtained by a polishing composition for a silicon wafer formed of an alkaline compound which is guanidine and water, or by further adding a metal oxide.

### SUMMARY OF INVENTION

However, conventional polishing compositions disclosed in Japanese Patent Application Laid-Open No. H05-154760 and International Publication No. 2008/004320 may not be concluded to have a sufficient polishing speed, and thus there has been a demand for a polishing composition capable of further improving the polishing speed.

Accordingly, the present invention has been made in view of the above problems, and has an object of providing a means for further improving a polishing speed in a polishing composition.

In addition, the present invention has an object of providing a polishing method using the polishing composition, and a method for producing a polishing-completed object to be polished, the method including polishing an object to be polished, using the polishing composition.

The present invention relates to a polishing composition including: an abrasive grain; hydrogen peroxide; and water, wherein the abrasive grain has an average secondary particle size of 20 nm or more to 150 nm or less, a molar concentration M (mmol/Kg) of the hydrogen peroxide and a total surface area of the abrasive grain satisfy a relationship of Formula 1 below and Formula 2 below, and a pH is 10 or more to 14 or less.

[Mathematical Formula 1]

M<Log(S)×100−750 (Formula 1)

M>0 (Formula 2)

(wherein S represents a total surface area (m²) of abrasive grains present in 1 Kg of the polishing composition, and Log(S) represents a natural logarithm of S).

### DESCRIPTION OF EMBODIMENTS

Hereinafter, an embodiment of the present invention is described. In addition, the present invention is not limited to the embodiment below. Further, unless specifically stated otherwise, operation and measurement of physical properties, and the like, are performed under conditions of room temperature (20° C. to 25° C.)/relative humidity of 40 to 50% RH.

Hereinafter, a polishing composition of the present invention is described in detail.

[Polishing Composition]

An embodiment of the present invention relates to a polishing composition including: an abrasive grain; hydrogen peroxide; and water, wherein the abrasive grain has an average secondary particle size of 20 nm or more to 150 nm or less, a molar concentration M (mmol/Kg) of the hydrogen peroxide and a total surface area of the abrasive grain satisfy a relationship of Formula 1 below and Formula 2 below, and a pH is 10 or more to 14 or less.

[Mathematical Formula 2]

M<Log(S)×100−750 (Formula 1)

M>0 (Formula 2)

(wherein S represents a total surface area (m²) of abrasive grains present in 1 Kg of the polishing composition, and Log(S) represents a natural logarithm of S).

The polishing composition according to an embodiment of the present invention having the constitution can improve a polishing speed.

In the polishing composition disclosed in the conventional art, namely, Japanese Patent Laid-Open Publication No. H05-154760 or International Publication No. 2008/004320, a strong base such as piperazine or guanidine, is used, and thus a polishing speed depends on solubility to an object to be polished due to basicity, that is, an etching force.

Thus, the present inventors reviewed various factors that are considered to affect the polishing speed for a purpose of further finding a condition for implementing improvement of the polishing speed by paying attention to an aspect other than the etching force.

As a result, the present inventors surprisingly found that, in the polishing composition containing hydrogen peroxide that was conventionally considered to lower the polishing speed, the polishing speed was remarkably improved when an abrasive grain having a predetermined average secondary particle size were contained in a predetermined amount and pH was adjusted to 10 or more to 14 or less. In addition, as a result of further review, the present inventors found that the polishing speed was remarkably improved when an addition amount of hydrogen peroxide and a total surface area of the abrasive grains present in the polishing composition satisfied a relationship represented by Formula 1 above and Formula 2 above, and completed the present invention.

The present inventors assume a mechanism in which the polishing speed is improved by the invention according to an embodiment of the present invention as follows. Here, the corresponding mechanism is described by describing a case where the object to be polished is a silicon material (Si) as an example, but the present invention is not limited thereto.

Addition of an oxidizing agent to the object to be polished generally oxidizes a surface of the object to be polished to lower solubility to the polishing composition of the object to be polished, and thus the polishing speed is lowered.

However, by adjusting the pH to be 10 or more to 14 or less while simultaneously using hydrogen peroxide as the oxidizing agent, the hydrogen peroxide dissociates in the polishing composition to generate H⁺ and HO₂⁻. Here, HO₂⁻ acts as a nucleophilic agent with respect to a silicon material surface which is the object to be polished, and Si near the surface, and thus a reaction intermediate having a structure represented by Si—O₂H is formed in an oxidation reaction process of hydrogen peroxide and the silicon material. The surface of the silicon material in a state in which the reaction intermediate is present is weaker than that in a state in which Si atoms are firmly bonded to each other by Si—Si bonds. Therefore, the surface of the silicon material in the state in which the reaction intermediate is present is easily broken due to stress occurring by physical contact with the abrasive grains, and as a result, the polishing speed is improved.

Here, in Formula 1 above, an upper limit of a molar concentration M of hydrogen peroxide having an effect of improving the polishing speed is represented as a function of the total surface area S of the abrasive grains in the polishing composition. That is, the above Formula 1 shows that the upper limit of the molar concentration M of hydrogen peroxide in which the effect of improving the polishing speed is exhibited is determined by a value of the total surface area S of the abrasive grains. This reason is considered as follows. As described above, by the presence of hydrogen peroxide in the polishing composition, the reaction intermediate is formed, and the polishing speed is improved. However, when hydrogen peroxide is excessively added to the polishing composition, a contact frequency of the abrasive grain relative to the amount of the reaction intermediate to be produced is relatively small. Here, a portion that is not in contact with the abrasive grains in the state of the reaction intermediate is oxidized as the reaction is completed, and the oxidized portion after the completion of the reaction of the silicon material has a lower etching property by the polishing composition which is basic. Thus, consequentially, the polishing speed is not improved, or the polishing speed is lowered. Here, since the contact frequency of the abrasive grain with the silicon material surface per unit time and per unit area is related to a surface area of the abrasive grain present in the polishing composition, the amount of reaction intermediate that is capable of being in contact with the abrasive grains on the silicon material surfaces is determined by the value of the total surface area S of the abrasive grains. In addition, the amount of the reaction intermediate is related to the molar concentration M of hydrogen peroxide. At this point, the upper limit of the molar concentration M of hydrogen peroxide is determined to be smaller than a value of a left side of Formula 1 above.

Also, in the above Formula 1, the upper limit of the molar concentration M of hydrogen peroxide is expressed by a logarithmic function of the total surface area S of the abrasive grains. Here, Formula 1 shows that as the total surface area S of the abrasive grains increases, the upper limit of the molar concentration M of hydrogen peroxide that exhibits the effect of improving the polishing speed is also increased, and as the total surface area S of the abrasive grains is increased, a degree of the increase in the upper limit of the molar concentration M of hydrogen peroxide (a change rate of an increase amount of the upper limit of the molar concentration M of hydrogen peroxide per unit increase amount of the total surface area S of the abrasive grains) is decreased. Here, the reason for which the upper limit of the molar concentration M of hydrogen peroxide that exhibits the effect of improving the polishing speed increased according to the increase in the total surface area S of the abrasive grains is that, as described above, it is thought that according to the increase in the total surface area of the abrasive grains, the amount of the reaction intermediate capable of being in contact with the abrasive grains on the surface of the silicon material is increased. Further, the reason for which a degree of the increase in the upper limit of the molar concentration M of hydrogen peroxide is decreased according to the increase in the total surface area S of the abrasive grains is that when an average secondary particle size of the abrasive grains is decreased, the total surface area S of the abrasive grains is increased, wherein it is thought that when the abrasive grain and the object to be polished contact, energy possessed by the abrasive grain is lowered, and thus an ability to mechanically destroy the surface of the object to be polished is lowered.

In addition, the above Formulas 1 and 2 show that when the total surface area S of the abrasive grains in the polishing composition is not a predetermined value or more, the effect of improving the polishing speed by the addition of hydrogen peroxide may not be obtained. This reason is considered as follows. As described above, the contact frequency of the abrasive grain with the silicon material surface per unit time and per unit area is related to the total surface area of the abrasive grains present in the polishing composition. From this, when the total surface area S of the abrasive grains is small, the amount of the reaction intermediate that is capable of being in contact with the abrasive grain on the surface of the silicon material is also decreased. At this time, collision does not occur at a collision frequency where the improvement of the polishing speed is significantly confirmed, and thus the effect of improving the polishing speed by the reaction intermediate may hardly be obtained, or oxidation by hydrogen peroxide is strongly exerted, and thus the polishing speed is not improved or the polishing speed is lowered.

In addition, the mechanism is based on assumption, and correctness and incorrectness do not affect the technical scope of the present invention.

(pH)

A pH of a polishing composition according to the present invention is 10 or more to 14 or less. The pH of the polishing composition relates to an amount of dissociation of hydrogen peroxide in the polishing composition and the etching force of the polishing composition.

When the pH is less than 10, it is difficult for the hydrogen peroxide to be dissociated in the polishing composition and the etching force of the polishing composition is also lowered, and thus an effect of improving a polishing speed may not be obtained. From the viewpoint of further increasing the effect of improving the polishing speed and obtaining a higher polishing speed, it is preferable that the pH is 11 or more. This is because it is thought that the amount of hydrogen peroxide dissociated in the polishing composition is further increased, and the etching force of the polishing composition can be further increased. In addition, it is preferable that the pH is 13 or less. This is because it is thought that when the pH is 13 or less, the amount of hydrogen peroxide dissociated in the polishing composition can be further increased. From the same viewpoint, it is more preferable that the pH is 12 or less. As an example in a preferred form according to the present invention, for example, a polishing composition in which the pH is 10 or more to 12 or less, and the like, may be included.

A method for controlling the pH is not particularly limited, but may include, for example, selection of an abrasive grain, a basic compound that is optionally usable, and other components (for example, an acidic compound, and the like) that are optionally usable to be described later, adjustment of an addition amount, or the like. Of these, the selection of the kind of basic compound or the adjustment of the addition amount is preferable. The pH value of the polishing composition can be confirmed by a pH meter. In addition, a detailed measurement method is described in Examples.

(Abrasive Grain)

A polishing composition of the present invention essentially includes an abrasive grain. The abrasive grain functions to mechanically polish a surface of an object to be polished.

The abrasive grain according to the present invention has an average secondary particle size of 20 nm or more to 150 nm or less. When the average secondary particle size is less than 20 nm, an effect of improving a polishing speed may not be obtained. This is because when the average secondary particle size of the abrasive grain is small, energy possessed by the abrasive grain is lowered when the abrasive grain and the object to be polished contact, and thus it is thought that it is difficult to mechanically destroy a surface of the object to be polished. Meanwhile, when the average secondary particle size is more than 150 nm, the effect of improving a polishing speed may not be obtained. This is because it is thought that it is difficult to adjust the total surface area of the abrasive grains in the polishing composition to be a predetermined level or more, and simultaneously an area of a portion where the abrasive grain and the object to be polished do not contact is increased. From the viewpoint of further increasing the effect of improving the polishing speed and obtaining a higher polishing speed, the average secondary particle size is preferably 100 nm or less, more preferably 50 nm or less, and even more preferably 30 nm or less. As an example of a preferred form according to the present invention, for example, a polishing composition in which the average secondary particle size of the abrasive grain is 20 nm or more to 100 nm or less may be included.

The average secondary particle size of the abrasive grain can be determined using a result of measurement of a volume average particle size by a dynamic light scattering method. In addition, a detailed measurement method is described in Examples.

In addition, an average primary particle size of the abrasive grain is not particularly limited. For example, a lower limit is preferably 5 nm or more, more preferably 7 nm or more, and even more preferably 10 nm or more. An upper limit of the average primary particle size of the abrasive grain is preferably 80 nm or less, more preferably 60 nm or less, and even more preferably 20 nm or less. Within this range, a secondary particle having the average secondary particle size can be more easily formed. In addition, the average primary particle size of the abrasive grain is calculated, for example, based on a specific surface area of the abrasive grain measured by a BET method.

Further, an addition amount of the abrasive grain in the polishing composition is preferably 1.5 mass % or more relative to a total mass of the polishing composition from the viewpoint of further increasing the effect of improving the polishing speed and obtaining a higher polishing speed. This is because it is thought that it is easy to adjust the total surface area of the abrasive grains to be a predetermined level or more, and thus a contact frequency between the abrasive grain and a reaction intermediate on the surface of the object to be polished is further increased, thereby further increasing the effect of improving the polishing speed by the hydrogen peroxide. Further, this is because it is thought that the number of abrasive grains themselves present in the polishing composition is large, and thus the contact frequency between the abrasive grain and the surface of the object to be polished per unit time and per unit area is further increased, thereby further increasing the effect of improving the polishing speed. From the same viewpoint, the addition amount of the abrasive grain in the polishing composition is more preferably 2 mass % or more, even more preferably 5 mass % or more, particularly preferably 20 mass % or more, and most preferably 25 mass % or more. Meanwhile, the addition amount of the abrasive grain in the polishing composition is preferably 50 mass % or less relative to a total mass of the polishing composition from the viewpoint of further increasing the effect of improving the polishing speed, obtaining a higher polishing speed, and further suppressing cost. This is because it is thought that when the addition amount of the abrasive grain in the polishing composition is 50 mass % or less, fluidity of the polishing composition is improved, and thus the contact frequency between the abrasive grain and the surface of the object to be polished per unit time and per unit area is increased. Further, this is because it is thought that among the abrasive grains present in the polishing composition, a component that is not in contact with the surface of the object to be polished during polishing treatment is decreased. From the same viewpoint, the addition amount of the abrasive grain in the polishing composition is more preferably 40 mass % or less, even more preferably 35 mass % or less, and particularly preferably 30 mass % or less.

The total surface area S (m²) of the abrasive grains present in 1 Kg of the polishing composition is not particularly limited as long as a range of a molar concentration M (mmol/Kg) of hydrogen peroxide with respect to 1 Kg of the polishing composition capable of satisfying the above Formulas 1 and 2 is a value that is capable of being present as a positive real number. Here, the total surface area S of the abrasive grains present in 1 Kg of the polishing composition is preferably 1900 m² or more from the viewpoint of further increasing the effect of improving the polishing speed and obtaining a higher polishing speed. This is because it is thought that the contact frequency between the abrasive grain and the reaction intermediate on the surface of the object to be polished is further increased, and thus the effect of improving the polishing speed by hydrogen peroxide is further increased. From the same viewpoint, the total surface area of the abrasive grains present in 1 Kg of the polishing composition is more preferably 6400 m² or more, even more preferably 10000 m² or more, even further more preferably 12000 m² or more, particularly preferably 25000 m² or more, and most preferably 32000 m² or more. In addition, the total surface area S of the abrasive grains present in 1 Kg of the polishing composition is preferably 65000 m² or less from the viewpoint of further increasing the effect of improving the polishing speed and obtaining a higher polishing speed. This is because, as described above, it is thought that deterioration in a mechanical polishing ability of the abrasive grain caused by a decrease in the average secondary particle size can be prevented by adjusting the total surface area S of the abrasive grains to be a predetermined value or less. Further, it is thought that the area of the portion where the abrasive grain and the object to be polished do not contact is capable of being decreased. From the same viewpoint, the total surface area S of the abrasive grains present in 1 Kg of the polishing composition is more preferably 52000 m² or less, and even more preferably 46000 m² or less.

In the present specification, the total surface area S of the abrasive grains present in 1 Kg of the polishing composition is calculated from the average secondary particle size and the addition amount of the abrasive grain, and a specific gravity of the abrasive grain. In addition, a detailed measurement method is described in Examples.

The abrasive grain is not particularly limited in view of the kind, and an inorganic particle, an organic particle, an organic-inorganic composite particle, and the like, can be used. Specific examples of the inorganic particle may include, for example, a particle formed of metal oxide such as silica, alumina, ceria, or titania, a silicon nitride particle, a silicon carbide particle, a boron nitride particle, and the like. Specific examples of the organic particle may include, for example, a latex particle, a polystyrene particle, a polymethyl methacrylate (PMMA) particle, and the like. The abrasive grain may be used alone or in a composite thereof or by mixing two kinds or more. In addition, the abrasive grain may be a commercially available product or a synthetic product.

As the abrasive grain, a silica particle is preferably used. The silica particle is not particularly limited, but for example, colloidal silica or fumed silica is more preferably used. Of these, the colloidal silica is even more preferably used from the viewpoint of further reducing scratches occurring on the surface of the object to be polished in a polishing process.

The kind of colloidal silica that is usable is not particularly limited, but for example, a surface-modified colloidal silica is also usable. Surface modification of the colloidal silica (supported colloidal silica) can be performed, for example, by mixing a metal such as aluminum, titanium, or zirconium, or an oxide thereof with colloidal silica and doping on a surface of the silica particle. Further, the surface modification of the colloidal silica can be performed by chemically bonding a functional group of an organic acid to the surface of the silica particle, that is, by immobilizing the organic acid.

(Hydrogen Peroxide)

A polishing composition of the present invention essentially includes hydrogen peroxide. The hydrogen peroxide is included in the polishing composition having a predetermined pH range, thereby improving a polishing speed of the polishing composition.

The reason for this is assumed as follows. The hydrogen peroxide dissociates in the polishing composition to produce H⁺ and HO₂⁻, and reacts with an object to be polished, thereby forming a reaction intermediate. In addition, a surface of the object to be polished in the state in which the reaction intermediate is present is weaker than the object to be polished itself, and thus the surface is easily destroyed by stress caused by physical contact due to a contact with the abrasive grain, thereby improving the polishing speed.

In addition, even though the reason that hydrogen peroxide among the various oxidizing agents shows a remarkable improvement effect of the polishing speed is unclear in detail, the present inventors consider that the reason is related to dissociation of the hydrogen peroxide to have a predetermined pH range, thereby generating HO₂⁻. More specifically, the present inventors consider that the reason is related to easy dissociation of hydrogen peroxide, the kind of counter ion, and an influence of these compounds on the polishing composition or the object to be polished, and the like.

The molar concentration M (mmol/Kg) of hydrogen peroxide with respect to 1 Kg of the polishing composition is not particularly limited as long as the molar concentration is a value in which a range capable of satisfying Formulas 1 and 2 above can be present in a relation between the molar concentration and the total surface area S (m²) of the abrasive grain present in 1 Kg of the polishing composition. Here, the molar concentration M of hydrogen peroxide with respect to 1 Kg of the polishing composition is preferably 25 mmol/Kg or more from the viewpoint of further increasing an effect of improving the polishing speed and obtaining a higher polishing speed. The reason is because it is thought that when the molar concentration M of hydrogen peroxide with respect to 1 Kg of the polishing composition is 25 mmol/Kg or more, by forming the reaction intermediate more largely, a portion of the surface of the object to be polished that is weak and capable of being mechanically easily broken by the abrasive grain, is further increased. From the same viewpoint, the molar concentration M of hydrogen peroxide with respect to 1 Kg of the polishing composition is more preferably 45 mmol/Kg or more, even more preferably 50 mmol/Kg or more, further more preferably 90 mmol/Kg or more, particularly preferably 100 mmol/Kg or more, and most preferably 140 mmol/Kg or more. Meanwhile, from the same viewpoint, an upper limit value having a preferable range is preferably 300 mmol/Kg or less. The reason is assumed as follows. First, since the molar concentration of hydrogen peroxide is not excessively high, formation of an oxidized portion in which the reaction is completed without contacting the abrasive grain in a reaction intermediate state may be further suppressed, and thus lowering of an etching property due to the increase in the oxidized portion may be further reduced. Further, as a result, the effect of improving the polishing speed may be further increased, and a higher polishing speed may be implemented. From the same viewpoint, the molar concentration M of hydrogen peroxide with respect to 1 Kg of the polishing composition is more preferably 250 mmol/Kg or less, even more preferably 200 mmol/Kg or less, particularly preferably 160 mmol/Kg or less, and most preferably 150 mmol/Kg or less.

(Water)

A polishing composition of the present invention essentially includes water. The water has a function as a solvent for dissolving each component or dispersing medium for dispersing each component, of the polishing composition.

From the viewpoint of inhibiting contamination of the object to be polished or an action of other components, water that does not contain impurities as possible is preferred. As the water that does not contain impurities as possible, for example, water in which a total content of transition metal ions is 100 ppb or less is preferable. Here, a purity of water can be increased by, for example, removal of impurity ions using an ion exchange resin, removal of a foreign material by a filter, an operation such as distillation. Specifically, it is preferable to use, for example, ion-exchanged water, pure water, ultrapure water, distilled water, or the like, as the water.

(Other Component)

The polishing composition according to an embodiment of the present invention may contain other components other than an abrasive grain, hydrogen peroxide, and water, if necessary. As the other components, for example, a basic compound, an acidic compound, a water-soluble polymer, an oxidizing agent other than hydrogen peroxide, a reducing agent, a surfactant, an antifungal agent, a chelating agent, and the like, may be included, but are not limited thereto.

Hereinafter, the basic compound, the acidic compound, the water-soluble polymer, the oxidizing agent other than hydrogen peroxide, the reducing agent, the surfactant, and the antifungal agent are described.

(Basic Compound)

A polishing composition according to an embodiment of the present invention preferably further includes a basic compound. The basic compound has a function of chemically polishing a surface of an object to be polished by etching and a function of improving dispersion stability of the abrasive grain. Further, the basic compound can be used as a pH adjusting agent.

Specific examples of the basic compound may include Group 2 element or a hydroxide of an alkali metal or a salt, a quaternary ammonium compound, ammonia, an amine, and the like. Here, the Group 2 element is not particularly limited, but an alkaline earth metal can be preferably used.

In the Group 2 element or the hydroxide of the alkali metal or the salt, calcium may be included as the Group 2 element, and potassium, sodium, and the like, may be included as the alkali metal. As the salt, carbonate, hydrogen carbonate, sulfate, acetate, and the like, may be included. More specifically, as the Group 2 element or the hydroxide of the alkali metal or the salt, for example, calcium hydroxide, potassium hydroxide, potassium carbonate, potassium hydrogen carbonate, potassium sulfate, potassium acetate, potassium chloride, sodium hydroxide, ammonium hydrogen carbonate, ammonium carbonate, sodium hydrogen carbonate, sodium carbonate, and the like, may be included.

As the quaternary ammonium compound, hydroxides such as tetramethyl ammonium, tetraethyl ammonium, and tetrabutyl ammonium, or salts such as chloride, carbonate, sulfate, and phosphate may be included. Specific examples thereof may include tetraalkylammonium hydroxide such as tetramethylammonium hydroxide, tetraethylammonium hydroxide, and tetrabutylammonium hydroxide, tetraalkylammonium hydroxide salts such as tetramethylammonium carbonate, and tetramethylammonium chloride, and the like.

Specific examples of the amine may include methylamine, dimethylamine, trimethylamine, ethylamine, diethylamine, triethylamine, ethylenediamine, monoethanolamine, N-(3-aminoethyl) ethanolamine, hexamethylenediamine, diethylene triamine, triethylenetetramine, piperazine anhydride, piperazine hexahydrate, 1-(2-aminoethyl)piperazine, N-methylpiperazine, guanidine, and the like.

Here, as the basic compound, a preferable compound may be selected according to an expected function thereof. From the viewpoint of improving the polishing speed, it is preferable that the basic compound includes a quaternary ammonium hydroxide compound such as tetramethylammonium hydroxide, a carbonate or a hydrogen carbonate. From the viewpoint of imparting a buffering action to the polishing composition and stabilizing the pH, the basic compound is preferably a mixture of the quaternary ammonium hydroxide compound and the carbonate or the hydrogen carbonate. In addition, from the viewpoint that the basic compound does not adhere to the object to be polished after polishing and does not remain, for example, quaternary ammonium hydroxide, amine, ammonia, and the like, are preferable.

In the polishing composition according to an embodiment of the present invention, among them, the Group 2 element or a hydroxide of an alkali metal or a salt is more preferable, and the hydroxide of the alkali metal or the salt is further more preferable, a carbonate or a hydrogen carbonate salt of the alkali metal is even more preferable, and the carbonate of the alkali metal is particularly preferable. Here, as the hydroxide of the alkali metal, potassium hydroxide or potassium hydroxide is preferable, and potassium hydroxide is more preferable. In addition, the carbonate of the alkali metal is preferably potassium carbonate or sodium carbonate, and more preferably potassium carbonate. That is, in the polishing composition according to an embodiment of the present invention, the basic compound is most preferably potassium carbonate.

The basic compound may be used alone, or in combination of two or more thereof.

A content of the basic compound in the polishing composition (a total amount thereof when two or more kinds are used) is preferably 0.01 mass % or more, relative to a total mass of the polishing composition. This is because an etching force can be further improved. Further, this is because it is thought that dissociation of hydrogen peroxide can be further promoted. From the same viewpoint, the content of the basic compound in the polishing composition is more preferably 0.03 mass % or more, and even more preferably 0.05 mass % or more. Meanwhile, the content of the basic compound in the polishing composition is preferably 10 mass % or less, relative to a total mass of the polishing composition. This is because it is considered that it can be easier to adjust a dissociation amount of hydrogen peroxide to a more appropriate range. From the same viewpoint, the content of the basic compound in the polishing composition is more preferably 5 mass % or less, and even more preferably 3 mass % or less.

(Acidic Compound)

A polishing composition according to an embodiment of the present invention may further include an acidic compound. The acidic compound can be used as a pH adjusting agent.

The acidic compound is not particularly limited and includes conventionally known acids. As the acid, inorganic acids such as hydrochloric acid, sulfuric acid, nitric acid, hydrofluoric acid, boric acid, carbonic acid, hypophosphorous acid, phosphorous acid, and phosphoric acid; organic acids such as formic acid, acetic acid, propionic acid, butyric acid, valeric acid, 2-methylbutyric acid, n-hexanoic acid, 3,3-dimethylbutyric acid, 2-ethylbutyric acid, 4-methylpentanoic acid, n-heptanoic acid, 2-methylhexanoic acid, n-octanoic acid, 2-ethylhexanoic acid, benzoic acid, glycolic acid, salicylic acid, glyceric acid, oxalic acid, malonic acid, succinic acid, glutaric acid, adipic acid, pimelic acid, maleic acid, phthalic acid, malic acid, tartaric acid, citric acid, lactic acid, diglycolic acid, 2-furancarboxylic acid, 2,5-furandicarboxylic acid, 3-furancarboxylic acid, 2-tetrahydrofurancarboxylic acid, methoxyacetic acid, methoxyphenylacetic acid, and phenoxyacetic acid may be included. Among these, the pH adjusting agent is preferably sulfuric acid, nitric acid, phosphoric acid, glycolic acid, succinic acid, maleic acid, citric acid, tartaric acid, malic acid, gluconic acid or itaconic acid. The acidic compound may be used alone, or in combination of two or more thereof.

An addition amount of the acidic compound is not particularly limited and may be suitably determined so that the polishing composition has a desired pH.

(Water-Soluble Polymer)

A polishing composition according to an embodiment of the present invention may further include a water-soluble polymer. The water-soluble polymer has a function of increasing wettability of a surface to be polished. The water-soluble polymer may be used alone, or in combination of two or more thereof.

As the water-soluble polymer, a water-soluble polymer having at least one functional group selected from a cationic group, an anionic group and a nonionic group in a molecule can be used. Specific examples of the water-soluble polymer may include those including a hydroxyl group, a carboxyl group, an acyloxy group, a sulfo group, a quaternary ammonium structure, a heterocyclic structure, a vinyl structure, a polyoxyalkylene structure, and the like, in a molecule. From the viewpoint of reducing an aggregate, improving cleaning property, or the like, a nonionic water-soluble polymer is preferred. As suitable examples, a polymer including an oxyalkylene unit, a polymer containing a nitrogen atom (nitrogen-containing water-soluble polymer), polyvinyl alcohol, a cellulose derivative, a starch derivative, and the like, are exemplified. More preferably, the water-soluble polymer is at least one selected from a polymer including an oxyalkylene unit, a polymer containing a nitrogen atom, polyvinyl alcohol and a cellulose derivative. The polymer containing a nitrogen atom and the cellulose derivative are even more preferable.

From the viewpoints of dispersion stability of the polishing composition and cleaning property of the silicon material, a weight average molecular weight of the water-soluble polymer is preferably 2,000,000 or less, more preferably 1,000,000 or less, even more preferably 500,000 or less, and particularly preferably 300,000 or less in polyethylene oxide conversion. In addition, a weight average molecular weight of the water-soluble polymer in the polishing composition is preferably 10,000 or more, more preferably 20,000 or more, and even more preferably 30,000 or more.

The water-soluble polymer may be used alone, or in combination of two or more thereof.

In addition, from the viewpoint of improving the wettability of a polished surface, a content of the water-soluble polymer in the polishing composition is preferably 0.0001 mass % or more, more preferably 0.001 mass % or more, and even more preferably 0.005 mass % or more, relative to a total mass of the polishing composition. Meanwhile, from the viewpoint of improving a polishing speed, the content of the water-soluble polymer is preferably 5 mass % or less, more preferably 1 mass % or less, and even more preferably 0.02 mass % or less, relative to a total mass of the polishing composition.

(Oxidizing Agent Other than Hydrogen Peroxide)

A polishing composition according to an embodiment of the present invention may further include an oxidizing agent other than hydrogen peroxide. The oxidizing agent other than hydrogen peroxide has a function of further improving a polishing efficiency on polishing a specific object to be polished in which the polishing efficiency is improved by adding the oxidizing agent other than hydrogen peroxide.

Specific examples of the oxidizing agent other than hydrogen peroxide may include peracetic acid, percarbonate, urea peroxide, perchloric acid; persulfates such as double salts with peroxide, for example, sodium persulfate, potassium persulfate, ammonium persulfuric acid, potassium monopersulfate (persulfuric acid), or oxone (2KHSO₅, KHSO₄, K2SO₄); halogen-based oxidizing agents such as hypochlorite, chlorite, chlorate, perchlorate, hypobromite, bromite, bromate, perbromate, hypoiodite, iodite, iodate, and periodate; compounds of a metal element capable of taking a wide range of oxidation number such as cerium ammonium nitrate, potassium permanganate, and potassium chromate, and the like. The oxidizing agent other than hydrogen peroxide may be used alone, or in combination of two or more thereof.

From the viewpoint of further improving the polishing efficiency on polishing the object to be polished in which the polishing efficiency is improved by adding the oxidizing agent, a content of the oxidizing agent other than hydrogen peroxide in the polishing composition is preferably 0.001 mass % or more, and more preferably 0.01 mass % or more, relative to a total mass of the polishing composition. Meanwhile, from the viewpoint of further suppressing a material cost, further reducing load of waste water treatment, and suppressing excessive oxidation on a surface of the object to be polished by the oxidizing agent, an upper limit of the content of the oxidizing agent other than hydrogen peroxide in the polishing composition is preferably 30 mass % or less, and more preferably 10 mass % or less, relative to a total mass of the polishing composition.

(Reducing Agent)

A polishing composition according to an embodiment of the present invention may further include a reducing agent. The reducing agent has a function of suppressing oxidation of any metal to suppress corrosion of the metal or to control the polishing efficiency.

As the reducing agent, conventionally known reducing agents used in the polishing composition can be contained. As an organic material, for example, hydrazine, formic acid, oxalic acid, formaldehyde aqueous solution, ascorbic acid, reducing sugars such as glucose may be included. As an inorganic material, for example, lithium aluminum hydride, sodium borohydride, a metal having a plurality of stable valences, and compounds thereof, and the like, may be included. The reducing agent may be used alone, or in combination of two or more thereof.

From the viewpoint of further improving a polishing efficiency without increasing an abrasive grain concentration, a lower limit of the content of the reducing agent in the polishing composition is preferably 0.001 mass % or more, and more preferably 0.01 mass % or more. Meanwhile, from the viewpoint of further suppressing a material cost, further reducing load of waste water treatment, and inhibiting excessive oxidation on a surface of the object to be polished by the oxidizing agent, the upper limit of the content of the reducing agent is preferably 30 mass % or less, and more preferably 10 mass % or less, relative to a total mass of the polishing composition.

(Chelating Agent)

A polishing composition according to an embodiment of the present invention may further include a chelating agent. The chelating agent has a function of suppressing residue of a metal impurity with respect to an object to be polished by trapping the metal impurity that is originally contained in the polishing composition or the metal impurity that occurs from the object to be polished or a polishing device during polishing or that is incorporated from the outside to form a complex. In particular, when the object to be polished is a semiconductor, the chelating agent suppresses the residue of the metal impurity to prevent metal contamination of the semiconductor, thereby suppressing deterioration of quality of the semiconductor.

As the chelating agent, for example, an aminocarboxylic acid-based chelating agent and an organic phosphonic acid-based chelating agent, and the like, may be included. Among the chelating agents, the organic phosphonic acid-based chelate is preferable, and ethylene diamine tetrakis (methylenephosphonic acid) is more preferable. The chelating agent may be used alone, or in combination of two or more thereof.

From the viewpoint of further increasing an effect of suppressing the metal impurity remaining in the object to be polished, a content of the chelating agent in the polishing composition is preferably 0.0001 mass % or more, more preferably 0.0005 mass % or more, and even more preferably 0.005 mass % or more, relative to a total mass of the polishing composition. Meanwhile, from the viewpoint of further increasing storage stability of the polishing composition, a content of the chelating agent in the polishing composition is preferably less than 0.5 mass %, more preferably less than 0.3 mass %, even more preferably less than 0.1 mass %, and particularly preferably less than 0.05 mass %.

(Surfactant)

A polishing composition according to an embodiment of the present invention may further include a surfactant. The surfactant has a function of imparting hydrophilicity to a polished surface after polishing to improve cleaning efficiency after polishing, thereby preventing adhesion of contaminant, or the like. In addition, the surfactant has a function of not only improving cleansing property, but also improving step performance such as dishing, by selecting an appropriate surfactant.

The surfactant may be any one of an anionic surfactant, a cationic surfactant, an amphoteric surfactant, and a nonionic surfactant. The surfactant may be used alone, or in combination of two or more thereof.

From the viewpoint of further improving the cleaning efficiency after polishing and further improving the step performance such as dishing, by selecting an appropriate surfactant, a content of the surfactant in the polishing composition is preferably 0.001 g/L or more, and more preferably 0.005 g/L or more.

(Antiseptic Agent⋅Antifungal Agent)

A polishing composition according to an embodiment of the present invention may further include an antiseptic agent⋅an antifungal agent.

As the antiseptic agent⋅antifungal agent, for example, an isothiazoline-based antiseptic agent such as 2-methyl-4-isothiazolin-3-one, Or 5-chloro-2-methyl-4-isothiazolin-3-one, paraoxybenzoic acid esters, phenoxyethanol, and the like, may be included. The antiseptic agent⋅antifungal agent may be used alone, or in combination of two or more thereof.

[Object to be Polished]

The object to be polished which is polished by using the polishing composition according to an embodiment of the present invention is not particularly limited, but is preferably a silicon-based material. As the silicon-based material, for example, a silicon material, a silicon oxide material, a silicon nitride material, and a silicon oxynitride material, and the like, may be included. Here, the silicon oxide material may be a cured material such as TEOS (tetraethoxysilane).

Of these, the silicon material is preferable in that an effect of the polishing composition according to an embodiment of the present invention can be obtained more remarkably. That is, it is preferable that the polishing composition according to an embodiment of the present invention is used for polishing the silicon material. The silicon material preferably includes at least one material selected from the group consisting of silicon single crystal, amorphous silicon and polysilicon. As the silicon material, the silicon single crystal or the polysilicon is more preferable, and the silicon single crystal is more preferable from the viewpoint of obtaining the effect of the present invention more remarkably.

In addition, the object to be polished is not particularly limited, but is preferably a semiconductor substrate.

[Method for Preparing Polishing Composition]

Another embodiment of the present invention provides a method for preparing a polishing composition obtained by mixing an abrasive grain; hydrogen peroxide; and water

so that the abrasive grain has an average secondary particle size of 20 nm or more to 150 nm or less,

a molar concentration M (mmol/Kg) of the hydrogen peroxide and a total surface area of the abrasive grain satisfy a relationship of Formula 1 below and Formula 2 below, and

a pH is 10 or more to 14 or less.

[Mathematical Formula 3]

M<Log(S)×100−750 (Formula 1)

M>0 (Formula 2)

(wherein S represents a total surface area (m²) of abrasive grains present in 1 Kg of the polishing composition, and Log(S) represents a natural logarithm of S).

The polishing composition can be prepared by mixing each component forming the polishing composition and, if necessary, other components. Here, the method for preparing the polishing composition is not particularly limited, but for example, may include a method for mixing each component, a method for mixing each component in a slurry line for supplying the polishing composition to a polishing pad, and a method of mixing each component on the polishing pad, and the like, before the polishing composition is applied to a polishing device. Of these, it is preferable to use the method of mixing each component before the polishing composition is applied to the polishing device.

When each component is mixed, it is preferable to perform stirring mixing. Further, a temperature at which each component is mixed is not particularly limited, but is preferably 0° C. or higher to 60° C. or lower, and more preferably 10° C. or higher to 40° C. or lower. When mixing each component, heating may be applied to increase a rate of dissolution. A mixing time is not particularly limited, but is preferably 1 second or more to 180 minutes or less.

In addition, details of the polishing composition to be prepared are the same as those described in explanation of the polishing composition according to an embodiment of the present invention.

[Polishing Method]

Still another embodiment of the present invention provides a polishing method of an object to be polished, using a polishing composition according to an embodiment of the present invention, or a polishing composition prepared by a preparation method according to another embodiment of the present invention.

As a polishing device, a general polishing device in which a holder holding a substrate having an object to be polished, or the like and a motor capable of changing the number of revolutions, or the like, is mounted, and in which a polishing table capable of attaching a polishing pad (polishing cloth) is provided, can be used. As the polishing device, specifically, for example, EPO113D (product of Ebara Corporation), or the like, can be used.

As the polishing pad, a general nonwoven fabric, polyurethane, and a porous fluororesin, and the like, can be used without particular limitation. It is preferable that the polishing pad is subjected to a groove process in which the polishing composition is gathered. As the polishing pad, specifically, for example, IC1000 (product of Nitta Haas Incorporated), or the like, can be used.

A polishing condition is not particularly limited. For example, a rotation speed of the polishing table is preferably 10 rpm or more to 500 rpm or less, and a pressure (polishing pressure) applied to the substrate having the object to be polished is preferably 300 hPa or more to 400 hPa or less. A method for supplying the polishing composition to the polishing pad is not particularly limited. For example, a method for continuously supplying the polishing composition by a pump, or the like, is employed. A supply amount of the polishing composition is not limited, but it is preferable that a surface of the polishing pad is always covered with the polishing composition according to an embodiment of the present invention. For example, the supply amount is preferably 10 ml/min or more to 1000 ml/min or less. Further, a polishing temperature is not particularly limited, but for example, is preferably 0° C. or higher to 60° C. or lower. In addition, a polishing time is not particularly limited, but for example, is preferably 1 second or more to 180 minutes or less. The polishing may be one-sided polishing or double-sided polishing. In addition, it is preferable to perform cleaning and drying after polishing.

Here, details of the object to be polished are the same as those described in the above description.

[Method for Producing Polishing-Completed Object to be Polished]

Still another embodiment of the present invention provides a method for producing a polishing-completed object to be polished, including: polishing an object to be polished using a polishing composition according to an embodiment of the present invention or a polishing method according to an embodiment of the present invention. It is preferable that the method for producing a polishing-completed object to be polished includes a process of cleaning and drying the object to be polished after the polishing process.

In addition, details of the object to be polished are the same as those described in the above description.

### EXAMPLES

The present invention is described in more detail with reference to Examples and Comparative Examples. However, the technical scope of the present invention is not limited to the following Examples.

### (1) Preparation of Polishing Composition

### Examples 1 to 13 and Comparative Examples 1 to 12

Colloidal silica (abrasive grain), and
hydrogen peroxide

were selected to have a composition shown in Table 2, potassium carbonate was further added in an amount of 3 mass % relative to a total mass of a polishing composition, and then mixed in pure water to prepare the polishing compositions of Examples 1 to 13 and Comparative Examples 1 to 12 having a pH of 11 (mixing temperature: about 25° C. and mixing time: about 10 minutes).

### Examples 14 and 15 and Comparative Examples 13 to 18

Colloidal silica (abrasive grain), and
hydrogen peroxide

were selected to have a composition shown in Table 3, potassium hydroxide (KOH) was further added in an amount so that a pH of a polishing composition was a value shown in Table 3, and then mixed in pure water to prepare the polishing compositions of Examples 14 and 15 and Comparative Examples 13 to 18 (mixing temperature: about 25° C. and mixing time: about 10 minutes).

### Comparative Example 19

Colloidal silica (abrasive grain), and
APS (ammonium persulfate)

were selected to have a composition shown in Table 4, potassium carbonate was further added in an amount of 3 mass % relative to a total mass of a polishing composition, and then mixed in pure water to prepare the polishing composition of Comparative Example 19 having a pH of 11 (mixing temperature: about 25° C. and mixing time: about 10 minutes).

Characteristics of each polishing composition are summarized in Tables 2 to 4.

(Measurement of pH of Polishing Composition)

The pH of the polishing composition (liquid temperature: 25° C.) was confirmed by a pH meter (HORIBA, Ltd., product model number: LAQUA (registered trademark)).

(Measurement of Average Secondary Particle Size of Abrasive Grain)

In addition, the average secondary particle size of the abrasive grain was measured by using a dynamic light scattering type particle size grain size distribution measuring device (Nikkiso Co., Ltd., product model number: UPA UT-151). First, the abrasive grains were dispersed in pure water to prepare a dispersion having a loading index (laser scattering strength) of 0.01. Then, a value of a volume average particle size Mv (value of D50) in a UT mode was measured byusing this dispersion, and the obtained value was determined as an average secondary particle size. The result is shown in Table 1.

In Tables 1 to 4, the abrasive grains A, B, C and E represent colloidal silicas in which only the average secondary particle size is different from each other.

TABLE 1

| Kind of colloidal silica | Average secondary particle size R [nm] |
|---|---|
| A | 10.0 |
| B | 201.9 |
| C | 80.1 |
| E | 20.5 |

(Calculation of Total Surface Area of Abrasive Grains in Polishing Composition)

Here, the total surface area of the abrasive grains in the polishing composition was measured as follows.

1. Assuming that the secondary particle of the abrasive grain is spherical, a radius r (m) of the secondary particle of the abrasive grain was calculated according to the following Equation from the average secondary particle size R (nm) of the abrasive grain obtained in the above measurement.

Radius r of secondary particle of abrasive grain (m)=(average secondary particle size R of abrasive grain (nm))/2×10⁻⁹[ Mathematical Formula 4]

2. A mass M (Kg) per one secondary particle of the abrasive grain was calculated according to the following Equation by using the radius r (m) of the secondary particle of the abrasive grain and a specific gravity ρ (Kg/m³) of the abrasive grain. Here, the specific gravity ρ of the abrasive grain was 2.3×10³ (Kg/m³), which is the specific gravity of the colloidal silica.

Mass M per one secondary particle of abrasive grain (Kg)={[4π×(radius r of secondary particle of abrasive grain (m))³]/3}×specific gravity ρ of abrasive grain (Kg/m³) [Mathematical Formula 5]

3. The number of abrasive grains N (number), which is the number of secondary particles of abrasive grains present in 1 Kg of the polishing composition, was calculated according to the following Equation.

The number of abrasive grains N (number)=(1 (Kg)×abrasive grain concentration (mass %))/mass M of one secondary particle of abrasive grain (Kg) [Mathematical Formula 6]

4. The total surface area S (m²) of the secondary particles of the abrasive grain present in 1 Kg of the polishing composition was calculated according to the following Formula by using the radius r (m) of the secondary particle of the abrasive grain and the number N of the abrasive grains (number).

Total surface area S of secondary particle of abrasive grain present in 1 Kg of polishing composition (m²)=[4λ×(radius r of secondary particle of abrasive grain (m))²]×the number of abrasive grains N (number) [Mathematical Formula 7]

The result is shown in Tables 2 to 4.

(2) Polishing

An 8-inch silicon single crystal substrate that can be used as a semiconductor substrate was polished under the following polishing conditions by using each of the polishing compositions obtained above.

<Polishing Condition>

One side polishing machine: EPO113D (Product of Ebara Corporation)

Polishing pad: Rigid polyurethane pad (IC1000 (Product of Nitta Haas Incorporated))

Pressure: 380 hPa

The number of revolutions of platen (table): 90 rpm

The number of revolutions of head (carrier): 87 rpm

Flow rate of polishing composition: 200 ml/min

Polishing time: 1 min

Holding temperature (polishing temperature) of polishing composition: 25° C.

(3) Measurement of Polishing Speed

1. A mass of the object to be polished (silicon single crystal substrate) before and after polishing was measured by using an electronic balance for wafer measurement TFT-300 (product of Shimadzu Corporation), and a mass change amount ΔM_{Si} (Kg) of the object to be polished before and after polishing was calculated from the difference.

2. A volume change amount ΔV_{Si} (m³) of the object to be polished before and after polishing was calculated by dividing the mass change amount ΔM_{Si} (Kg) of the object to be polished before and after polishing by the specific gravity of silicon of 2.33×10³ (Kg/m³).

3. A thickness change amount Δd_{Si} (m) of the object to be polished before and after polishing was calculated by dividing the volume change amount ΔV_{Si} (m³) of the object to be polished before and after polishing by an area S_{Si} (m²) of a polished surface of the object to be polished.

4. The thickness change amount Δd_{Si} (m) of the object to be polished before and after polishing was divided by a polishing time t (min), and further converted into a unit (Å/min). This value was determined as a polishing speed v_{Si} (Å/min).

The result is shown in Tables 2 to 4.

Further, “a value of a right side in Formula 1” in the Table indicates a calculation result of the right side in Formula 1 below.

[Mathematical Formula 8]

M<Log(S)×100−750 (Formula 1)

M>0 (Formula 2)

(wherein S represents a total surface area (m²) of abrasive grains present in 1 Kg of the polishing composition, and Log(S) represents a natural logarithm of S).

(4) Calculation of Polishing Speed Ratio for System in which Oxidizing Agent is Absent

With respect to the polishing speed when each of the polishing compositions measured in (3) above was used, a polishing speed ratio (%) of each of the polishing compositions including hydrogen peroxide or ammonium persulfate (APS) to a polishing composition that was prepared in the same manner as above except that hydrogen peroxide or APS was not included, was calculated.

More specifically, Comparative Example 1 for Comparative Example 2, Comparative Example 3 for Comparative Example 4, Comparative Example 5 for Examples 1 to 3 and Comparative Examples 6 and 19, Comparative Example 7 for Example 4 and Comparative Example 8, Comparative Example 9 for Examples 5 to 8 and Comparative Example 10, Comparative Example 11 for Examples 9 to 13 and Comparative Example 12, Comparative Example 13 for Comparative Example 14, Comparative Example 15 for Comparative Example 16, Comparative Example 17 for Example 14, and Comparative Example 18 for Example 15 were selected as the polishing compositions in which hydrogen peroxide or ammonium persulfate was not included, respectively, and the polishing speed ratio (%) when the polishing speed was 100% was calculated.

In addition, when the polishing speed ratio was 101% or more, an effect of improving the polishing speed could be confirmed significantly. The result is shown in Tables 2 to 4.

TABLE 2

| | Abrasive grain | | | | | | | Polishing speed |
|---|---|---|---|---|---|---|---|---|
| | | | | Total | | Hydrogen | | ratio for system |
| | Kind of | Addition | | surface | Value of | peroxide | Polishing | in which hydrogen |
| | colloidal | amount | Number N | area S | right side | concentration | speed V_{Si} | peroxide is absent |
| | silica | [mass %] | [number/Kg] | [m²/Kg] | in Formula 1 | [mmol/Kg] | [Å/min] | [%] |
| Comparative Example 1 | A | 6 | 5.0 × 10¹⁹ | 15652 | 216 | 0 | 13477 | — |
| Comparative Example 2 | A | 6 | 5.0 × 10¹⁹ | 15652 | 216 | 50 | 11324 | 84 |
| Comparative Example 3 | B | 2 | 2.0 × 10¹⁵ | 258 | −195 | 0 | 12445 | — |
| Comparative Example 4 | B | 2 | 2.0 × 10¹⁵ | 258 | −195 | 50 | 9219 | 74 |
| Comparative Example 5 | C | 24 | 3.9 × 10¹⁷ | 7816 | 146 | 0 | 13456 | — |
| Example 1 | C | 24 | 3.9 × 10¹⁷ | 7816 | 146 | 45 | 16723 | 124 |
| Example 2 | C | 24 | 3.9 × 10¹⁷ | 7816 | 146 | 90 | 17632 | 131 |
| Example 3 | C | 24 | 3.9 × 10¹⁷ | 7816 | 146 | 135 | 14803 | 110 |
| Comparative Example 6 | C | 24 | 3.9 × 10¹⁷ | 7816 | 146 | 180 | 12552 | 93 |
| Comparative Example 7 | E | 2 | 1.9 × 10¹⁸ | 2545 | 34 | 0 | 13025 | — |
| Example 4 | E | 2 | 1.9 × 10¹⁸ | 2545 | 34 | 25 | 13569 | 104 |
| Comparative Example 8 | E | 2 | 1.9 × 10¹⁸ | 2545 | 34 | 50 | 12370 | 95 |
| Comparative Example 9 | E | 20 | 1.9 × 10¹⁹ | 25451 | 264 | 0 | 12288 | — |
| Example 5 | E | 20 | 1.9 × 10¹⁹ | 25451 | 264 | 50 | 17243 | 140 |
| Example 6 | E | 20 | 1.9 × 10¹⁹ | 25451 | 264 | 100 | 23421 | 191 |
| Example 7 | E | 20 | 1.9 × 10¹⁹ | 25451 | 264 | 200 | 19942 | 162 |
| Example 8 | E | 20 | 1.9 × 10¹⁹ | 25451 | 264 | 250 | 15749 | 128 |
| Comparative Example 10 | E | 20 | 1.9 × 10¹⁹ | 25451 | 264 | 275 | 11930 | 97 |
| Comparative Example 11 | E | 30 | 2.9 × 10¹⁹ | 38176 | 305 | 0 | 13046 | — |
| Example 9 | E | 30 | 2.9 × 10¹⁹ | 38176 | 305 | 100 | 21856 | 168 |
| Example 10 | E | 30 | 2.9 × 10¹⁹ | 38176 | 305 | 150 | 24869 | 191 |
| Example 11 | E | 30 | 2.9 × 10¹⁹ | 38176 | 305 | 200 | 20778 | 159 |
| Example 12 | E | 30 | 2.9 × 10¹⁹ | 38176 | 305 | 250 | 18893 | 145 |
| Example 13 | E | 30 | 2.9 × 10¹⁹ | 38176 | 305 | 300 | 14000 | 107 |
| Comparative Example 12 | E | 30 | 2.9 × 10¹⁹ | 38176 | 305 | 350 | 10548 | 81 |

TABLE 3

| | Abrasive grain | | | | | | | | Polishing speed |
|---|---|---|---|---|---|---|---|---|---|
| | | | | Total | | Hydrogen | | | ratio for system |
| | Kind of | Addition | | surface | Value of | peroxide | | Polishing | in which hydrogen |
| | colloidal | amount | Number N | area S | right side | concentration | | speed v_{Si} | peroxide is absent |
| | silica | [mass %] | [number/Kg] | [m²/Kg] | in Formula 1 | [mmol/Kg] | pH | [Å/min] | [%] |
| Comparative Example 13 | E | 20 | 1.9 × 10¹⁹ | 25451 | 264 | 0 | 7 | 2693 | — |
| Comparative Example 14 | E | 20 | 1.9 × 10¹⁹ | 25451 | 264 | 100 | 7 | 1408 | 52 |
| Comparative Example 15 | E | 20 | 1.9 × 10¹⁹ | 25451 | 264 | 0 | 9 | 5262 | — |
| Comparative Example 16 | E | 20 | 1.9 × 10¹⁹ | 25451 | 264 | 100 | 9 | 4593 | 87 |
| Comparative Example 17 | E | 20 | 1.9 × 10¹⁹ | 25451 | 264 | 0 | 10 | 6783 | — |
| Example 14 | E | 20 | 1.9 × 10¹⁹ | 25451 | 264 | 100 | 10 | 8930 | 132 |
| Comparative Example 18 | E | 20 | 1.9 × 10¹⁹ | 25451 | 264 | 0 | 11 | 8502 | — |
| Example 15 | E | 20 | 1.9 × 10¹⁹ | 25451 | 264 | 100 | 11 | 15452 | 182 |

TABLE 4

| | Abrasive grain | | | | | | | | Polishing speed |
|---|---|---|---|---|---|---|---|---|---|
| | | | | Total | | | | | ratio for system |
| | Kind of | Addition | | surface | Value of | Oxidizing agent | | Polishing | in which hydrogen |
| | colloidal | amount | Number N | area S | right side | | Concentration | speed v_{Si} | peroxide is absent |
| | silica | [mass %] | [number/Kg] | [m²/Kg] | in Formula 1 | Kind | [mmol/Kg] | [Å/min] | [%] |
| Comparative | C | 24 | 3.9 × 10¹⁷ | 7816 | 146 | None | 0 | 13456 | — |
| Example 5 | | | | | | | | | |
| Example 1 | C | 24 | 3.9 × 10¹⁷ | 7816 | 146 | Hydrogen | 45 | 16723 | 124 |
| | | | | | | peroxide | | | |
| Comparative | C | 24 | 3.9 × 10¹⁷ | 7816 | 146 | APS (ammonium | 45 | 13518 | 100 |
| Example 19 | | | | | | persulfate) | | | |

From the above results, it was confirmed that the polishing compositions of Examples could obtain an excellent effect of improving the polishing speed as compared with the polishing compositions of Comparative Examples. Here, it could be confirmed from comparison of Comparative Example 5, Comparative Example 19, and Example 1 that the effect of the present invention could be obtained in the system containing the oxidizing agent while simultaneously the oxidizing agent is hydrogen peroxide.

Here, Comparative Example 7, Comparative Example 8, and Example 4 were polishing compositions that were different, respectively, at ranges in which the addition amount of the abrasive grain was 2 mass % and the hydrogen peroxide concentration was 0 mmol/Kg or more to 50 mmol/Kg or less. In addition, Comparative Example 9, Comparative Example 10, and Examples 5 to 8 were polishing compositions that were different, respectively, at ranges in which the addition amount of the abrasive grain was 20 mass % and the hydrogen peroxide concentration was 0 mmol/Kg or more to 275 mmol/Kg or less. Further, Comparative Example 11, Comparative Example 12, and Examples 9 to 13 were polishing compositions that were different, respectively, at ranges in which the addition amount of the abrasive grain was 30 mass % and the hydrogen peroxide concentration was 0 mmol/Kg or more to 350 mmol/Kg or less. Here, in the comparison of the polishing compositions in which the addition amount of the abrasive grain was the same, the polishing composition showing the highest polishing speed and most excellent effect of improving the polishing speed (polishing speed ratio) was Example 4 in which the hydrogen peroxide concentration was 25 mmol/Kg when the addition amount of the abrasive grain was 2 mass %, Example 6 in which the hydrogen peroxide concentration was 100 mmol/Kg when the addition amount of the abrasive grain was 20 mass %, and Example 10 in which the hydrogen peroxide concentration was 150 mmol/Kg when the addition amount of the abrasive grain was 30 mass %. Further, it was confirmed from comparison of Example 4, Example 6, and Example 10 that when the addition amount of the abrasive grain was 20 mass % and 30 mass %, a better effect of improving the polishing speed could be obtained. It was also confirmed that when the addition amount of the abrasive grain was 20 mass % or 30 mass %, a better polishing speed could be obtained, and when the addition amount of the abrasive grain was 30 mass %, a much better polishing speed could be obtained.

In addition, Comparative Examples, Comparative Example 6, and Examples 1 to 3 were polishing compositions that were different, respectively, at ranges in which the addition amount of the abrasive grain was 24 mass %, the average secondary particle size of the abrasive grain was 80.1 nm, and the hydrogen peroxide concentration was 0 mmol/Kg or more to 180 mmol/Kg or less. In addition, Comparative Example 9, Comparative Example 10, and Examples 5 to 8 were polishing compositions that were different, respectively, at ranges in which the addition amount of the abrasive grain was 20 mass %, the average secondary particle size of the abrasive grain was 20.5 nm, and the hydrogen peroxide concentration was 0 mmol/Kg or more to 275 mmol/Kg or less. In addition, Comparative Example 11, Comparative Example 12, and Examples 9 to 13 were polishing compositions that were different, respectively, at ranges in which the average addition amount of the abrasive grain was 30 mass %, the average secondary particle size of the abrasive grain was 20.5 nm, and the hydrogen peroxide concentration was 0 mmol/Kg or more to 350 mmol/Kg or less. Here, in the comparison of the polishing compositions in which the addition amount of the abrasive grain was 20 mass % or more to 30 mass % or less, and the average secondary particle size was the same, the polishing composition showing a high polishing speed and excellent effect of improving the polishing speed (polishing speed ratio) was Example 2 in which the hydrogen peroxide concentration was 90 mmol/Kg in the system in which the average secondary particle size of the abrasive grain was 80.1 nm, Example 6 in which the hydrogen peroxide concentration was 100 mmol/Kg, and Example 10 in which the hydrogen peroxide concentration was 150 mmol/Kg, in the polishing composition in which the average secondary particle size of the abrasive grain was 20.5 nm. In addition, it was confirmed from the comparison of Example 2, Example 6, and Example 10 that when the average secondary particle size of the abrasive grain was 20.5 nm, a better effect of improving the polishing speed could be obtained.

In addition, Comparative Examples 14 and 16 and Examples 14 and 15 were polishing compositions that were different, respectively, at a range in which the pH was 7 or more to 11 or less. It was confirmed from comparison that the effect of the present invention could be obtained in a system in which the pH was 10 or more. Further, it was confirmed from comparison between Example 14 and Example 15 that a system having the pH of 11 could obtain a higher polishing speed while simultaneously obtaining a better effect of improving the polishing speed as compared with the system having the pH of 10.

Further, Examples 6 and 15 were polishing compositions including different basic compounds to be used. It was confirmed from these comparison results that a system using potassium carbonate as the basic composition could obtain a higher polishing speed while simultaneously obtaining a better effect of improving the polishing speed as compared with a system using KOH as the basic composition.

The present application is based on Japanese patent application No. 2015-201340 filed on Oct. 9, 2015, and a disclosed content thereof is incorporated herein as a whole by reference.

1. A polishing composition comprising:
an abrasive grain;
hydrogen peroxide; and
water,
wherein the abrasive grain has an average secondary particle size of 20 nm or more to 150 nm or less,
a molar concentration M (mmol/Kg) of the hydrogen peroxide and a total surface area of the abrasive grain satisfy a relationship of Formula 1 below and Formula 2 below, and
a pH is 10 or more to 14 or less.
[Mathematical Formula 1]
M<Log(S)×100−750 (Formula 1)
M>0 (Formula 2)
(wherein S represents a total surface area (m²) of abrasive grains present in 1 Kg of the polishing composition, and Log(S) represents a natural logarithm of S).

2. The polishing composition according to claim 1, wherein the polishing composition is used for polishing a silicon material.

3. The polishing composition according to claim 1, further comprising a basic compound.

4. The polishing composition according to claim 1, wherein the abrasive grain is a colloidal silica.

5. The polishing composition according to claim 1, wherein the average secondary particle size of the abrasive grain is 20 nm or more to 100 nm or less.

6. The polishing composition according to claim 1, wherein the pH is 10 or more to 12 or less.

7. A polishing method of an object to be polished, using the polishing composition according to claim 1.

8. A method for producing a polishing-completed object to be polished, comprising: polishing an object to be polished using the polishing composition according to claim 1.
